(19) United States
(12) Patent Application Publication
(10) Pub. No.: US 2024/0334699 A1
(43) Pub. Date: Oct. 3, 2024

(54) THREE-DIMENSIONAL MEMORY DEVICE

(71) Applicant: SAMSUNG ELECTRONICS CO., LTD., Suwon-si (KR)

(72) Inventors: Younghak Son, Suwon-si (KR); Kyunghwa Yun, Suwon-si (KR); Chanho Kim, Suwon-si (KR)

(21) Appl. No.: 18/424,495

(22) Filed: Jan. 26, 2024

(30) Foreign Application Priority Data
Mar. 29, 2023 (KR) 10-2023-0041560

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80895; H01L 2224/80896; H01L 2924/1431; H01L 2924/14511

(57) ABSTRACT

An example memory device includes a plurality of memory blocks, each including a cell region and a cell wiring region. At least one memory block includes a wordline pattern portion and a channel structure. The wordline pattern portion is provided in the cell region and the cell wiring region, and includes wordlines spaced apart from each other and stacked in a first direction. The channel structure is provided in the cell region to extend in the first direction. The wordline pattern portion extends a second direction, perpendicular to the first direction, when viewed from above, and has at least one staircase portion including a first staircase pattern, having sequentially descending staircases, and a second staircase pattern, having sequentially ascending staircases. The first staircase pattern and the second staircase pattern are provided in different numbers in the at least one memory block.

### CROSS-REFERENCE TO RELATED APPLICATION

This application claims benefit of priority to Korean Patent Application No. 10-2023-0041560, filed on Mar. 29, 2023, in the Korean Intellectual Property Office, the disclosure of which is incorporated herein by reference in its entirety.

### BACKGROUND

The present disclosure relates to memory devices, and more particularly, to a memory device having a three-dimensional structure.

Recently, as information communication devices have become more multifunctional, there is demand for increasing capacity and integration of memory devices. As a cell size is reduced to achieve higher integration, operating circuits and/or wiring structures, included in memory devices to control operation and electrical connection of the memory devices, are becoming more complex. Accordingly, there is demand for memory devices for increasing integration density while maintaining performance of the memory devices. For example, in a structure stacked in a direction perpendicular to a substrate, the number of wordlines may be increased and a space is required to connect a plurality of wordlines to each other, resulting in difficulty in reducing a size of a memory device.

### SUMMARY

The present disclosure relates to a memory device having high integration and significantly reduced size achieved by optimizing a structure in an element.

In some implementations, a memory device includes a plurality of memory blocks, each including a cell region and a cell wiring region. At least one memory block may include: a wordline pattern portion provided in the cell region and the cell wiring region and including wordlines spaced apart from each other and stacked in a first direction; and a channel structure provided in the cell region to extend in the first direction. The wordline pattern portion may extend a second direction, perpendicular to the first direction, when viewed from above, and may have at least one staircase portion including a first staircase pattern, having sequentially descending staircases, and a second staircase pattern having sequentially ascending staircases. The first staircase pattern and the second staircase pattern may be provided in different numbers in the at least one memory block.

In some implementations, the staircase portion may be provided in plural and may include a first staircase portion and a second staircase portion spaced apart from each other in the second direction.

In some implementations, the number of the first staircase patterns of the first staircase portion and the number of the first staircase patterns of the second staircase portion, and the number of the second staircase patterns of the first staircase portion and the number of the second staircase patterns of the second staircase portion are different from each other.

In some implementations, the staircases constituting the first staircase pattern and the second staircase pattern may correspond to the wordlines in a one-to-one correspondence. In addition, the wordlines may sequentially correspond to an uppermost staircase, among the staircases of the first and second staircase patterns, to a lowermost staircase among the staircases of the first and second staircase patterns.

In some implementations, in the wordlines, respective staircases of the first and second staircase patterns may have different heights.

In some implementations, when the first staircase pattern and/or the second staircase pattern is provided in plural, the plurality of first staircase patterns and/or the plurality of second staircase patterns may be arranged in a third direction, perpendicular to the first direction and the second direction.

In some implementations, the memory blocks may be arranged in the third direction, and a trench may be provided between the adjacent memory blocks and may have an inclined portion inclined in the second direction when viewed from above. When two adjacent memory blocks are a first memory block and a second memory block, the first and second memory blocks may have widths varying depending on a disposition of the staircase portion in the first and second regions, and may have an interdigitated shape.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram of an example of a memory device.

FIG. 2 is a diagram illustrating an example of a memory cell array including a plurality of memory blocks.

FIG. 3 is a circuit diagram illustrating an example of an i-th memory block.

FIG. 4A is a plan view illustrating an example of a memory device including two adjacent memory blocks, and FIG. 4B is a diagram illustrating an example of an order of end staircases in wordlines of FIG. 4A.

FIG. 5 is an example cross-sectional view taken along line A-A′ of FIG. 4A.

FIG. 6 is an example conceptual perspective view of the memory device of FIG. 4.

FIG. 7 is a cross-sectional view illustrating an example memory device including a wiring connected to wordlines.

FIG. 8 is a cross-sectional view illustrating another example memory device including a structure of a first semiconductor layer.

FIG. 9 is a plan view illustrating an example memory device including different numbers of first and second staircase patterns.

FIG. 10 is a plan view illustrating an example of disposing memory blocks in a memory device.

FIG. 11 is a plan view illustrating another example of disposing memory blocks in a memory device.

FIG. 12A is a plan view illustrating another example of a memory device including two adjacent memory blocks, and FIG. 12B is a diagram illustrating an example of an order of end staircases in wordlines of FIG. 12A.

FIG. 13 is a conceptual perspective view of another example of a memory device.

### DETAILED DESCRIPTION

Hereinafter, example implementations will be described with reference to the accompanying drawings.

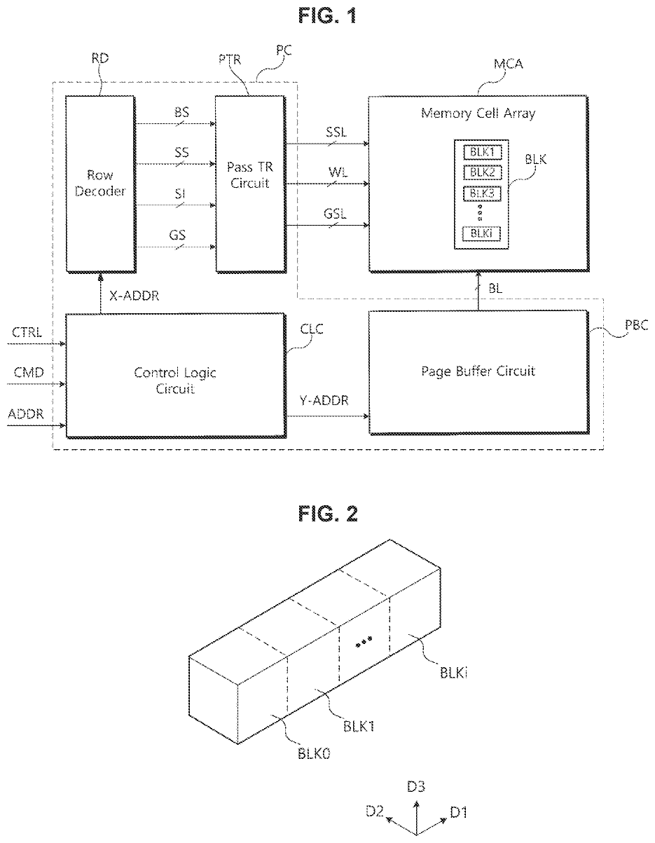

FIG. 1 is a block diagram of an example of a memory device.

Referring to FIG. 1, a memory device may include a memory cell array MCA and a peripheral circuit PC. The peripheral circuit PC may include a pass transistor circuit P_TR, a row decoder RD, a control logic circuit CLC, and a page buffer circuit PBC. Although not illustrated in the drawing, the peripheral circuit PC may further include a voltage generation unit, a data input/output circuit, an input/output interface, a temperature sensor, a command decoder, or an address decoder. In some implementations, the memory device may be a nonvolatile memory device. Hereinafter, a “memory device” will be referred to as a “nonvolatile memory device.”

The memory cell array MCA may include a plurality of memory blocks BLK1 to BLKi. Each of the memory blocks BLK1 to BLKi may include a plurality of memory cells. The memory cell blocks BLK1 to BLKi may be connected to bitlines BL, wordlines WL, at least one string select line SSL, and at least one ground select line GSL. For example, the memory cell array MCA may be connected to the pass transistor circuit P_TR through wordlines WL, string select lines SSL, and ground select lines GSL, and may be connected to the page buffer circuit PBC through bitlines BL. The memory cell array MCA may include a plurality of memory cells, and the memory cells may be, for example, flash memory cells. Hereinafter, example implementations will be described under the assumption that the plurality of memory cells are NAND flash memory cells. However, example implementations are not limited thereto and, in some implementations, the plurality of memory cells may be resistive memory cells such as resistive RAM (ReRAM) cells, a phase change RAM (PRAM) cells, or a magnetic RAM (MRAM) cells.

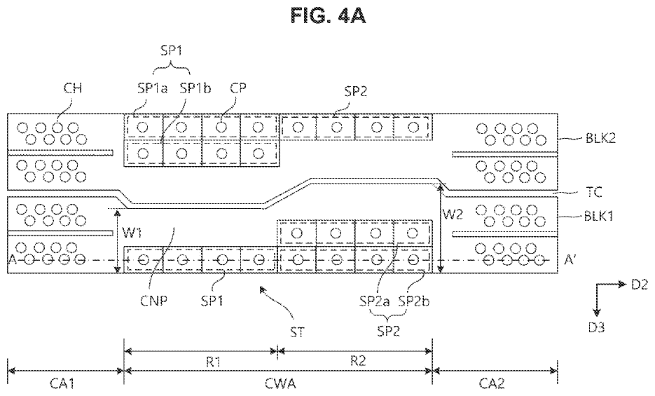

In an example, the memory cell array MCA may include a three-dimensional (3D) memory cell array, the 3D memory cell array may include a plurality of NAND strings, and each of the plurality of NAND strings may include memory cells, respectively connected to wordlines stacked on a substrate to be perpendicular to the substrate, which will be described with reference to FIG. 3 in addition to FIG. 1. However, example implementations are not limited thereto and, in some implementations, the MCA may include a two-dimensional (2D) memory cell array and the 2D memory cell array may include a plurality of NAND strings disposed in row and column directions.

The control logic circuit CLC may generate various control signals for programming data in the memory cell array MCA, reading data from the memory cell array MCA, or erasing data stored in the memory cell array MCA, based on a command CMD, an address ADDR, and a control signal CTRL. For example, the control logic circuit CLC may output a row address X-ADDR and a column address Y-ADDR. Accordingly, the control logic circuit CLC may generally control various operations in the memory device.

The row decoder RD may output a block select signal for selecting one of the plurality of memory blocks to block select signal lines BS in response to the row address X-ADDR. Also, the row decoder RD may output a wordlines driving signal for selecting one of wordlines WL of the selected memory block to wordline driving signal lines SI, output a string select line driving signal for selecting one of string select lines SSL to string select line driving signal lines SS, and output a ground select line driving signal for selecting one of the ground select lines GSL to ground select line driving signal lines GS, in response to the row address X-ADDR. The page buffer circuit may select some bitlines, among the bitlines BL, in response to the column address Y-ADDR. For example, the page buffer circuit PBC may operate as a write driver or a sense amplifier according to a mode of operation.

The pass transistor circuit P_TR may be connected to the row decoder RD through the block select signal lines BS, the string select line driving signal lines SS, the wordline driving signal lines SI, and the ground select line driving signal lines GS. The string select line driving signal lines SS, the wordline driving signal lines SI, and the ground select line driving signal lines GS may be referred to as “driving signal lines.” The pass transistor circuit P_TR may include a plurality of pass transistors which may be controlled by block select signals received through the block select signal lines BS, and may provide string select line driving signals, the wordline driving signals, and the ground select line driving signals to the string select lines SSL, the wordlines WL, and the ground select lines GSL, respectively.

In the example memory device, the memory cell array and the peripheral circuit may be fabricated as separate semiconductor layers, and may then be stacked. In this case, the memory device may have a structure in which the MCA is disposed on a portion of the peripheral circuit, for example, a cell-over-periphery (COP) structure.

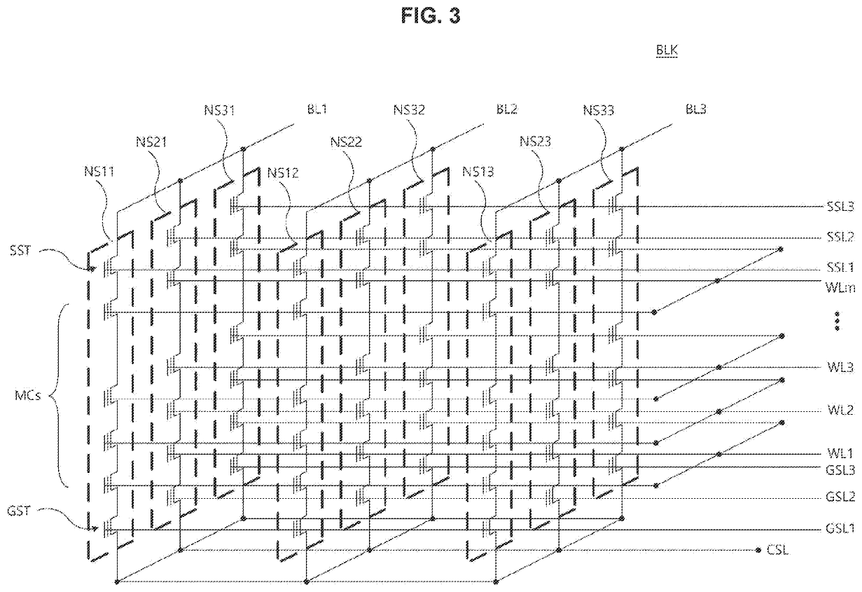

FIG. 2 is a diagram illustrating an example of a memory cell array including a plurality of memory blocks, and FIG. 3 is a circuit diagram illustrating an example of an i-th memory block.

Referring to FIGS. 1 to 3, the memory cell array MCA may include a plurality of memory blocks BLK0 to BLKi (where i is a positive integer). Each of the plurality of memory blocks BLK0 to BLKi may have a three-dimensional structure (or a vertical structure). For example, each of the plurality of memory blocks BLK0 to BLKi may include a plurality of NAND strings extending in a third direction. Each of the plurality of memory blocks BLK0 to BLKi may also include a ground select line GSL, a plurality of wordlines WL1 to WLm (where m is a positive integer), and a string select line SSL.

In this case, the plurality of NAND strings may be spaced apart from each other by a specific distance in first and second directions. The plurality of memory blocks BLK0 to BLKi may be selected by the row decoder (RD in FIG. 1). For example, the row decoder RD may select a memory block corresponding to a block address from among the plurality of memory blocks BLK0 to BLKi.

In an example, first NAND strings NS11, NS21, and NS31 may be provided between a bitline BL1 and a common source line CSL, second NAND strings NS12, NS22, and NS32 may be provided between a bitline BL2 and the common source line CSL, and third NAND strings NS13, NS23, and NS33 may be provided between a bitline BL3 and the common source line CSL. Each NAND string (for example, NS33) may include a string select transistor SST, a plurality of memory cells MCs, and a ground select transistor GST connected in series.

The string select transistor SST may be connected to corresponding string select lines SSL1 to SSL3 (SSL). Each of the plurality of memory cells MCs may be connected to corresponding wordlines WL1 to WLm (WL). The ground select transistor GST may be connected to corresponding ground select lines GSL1 to GSL3. The string select transistor SST may be connected to corresponding bitlines BL1 to BL3, and the ground select transistor GST may be connected to the common source line CSL.

In the example, wordlines (for example, WL1) having the same height, for example, wordlines disposed at the same level may be commonly connected to each other, the string select lines SSL1 to SSL3 may be separated from each other, and the ground select lines GSL1 to GSL3 may also be separated from each other.

The number of NAND strings, the number of wordlines WL, the number of bitlines BL, the number of ground select lines GSL, and the number of string select lines SSL may vary in some implementations.

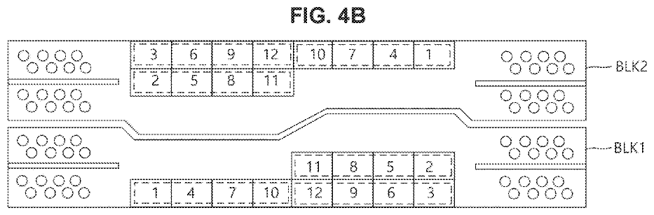

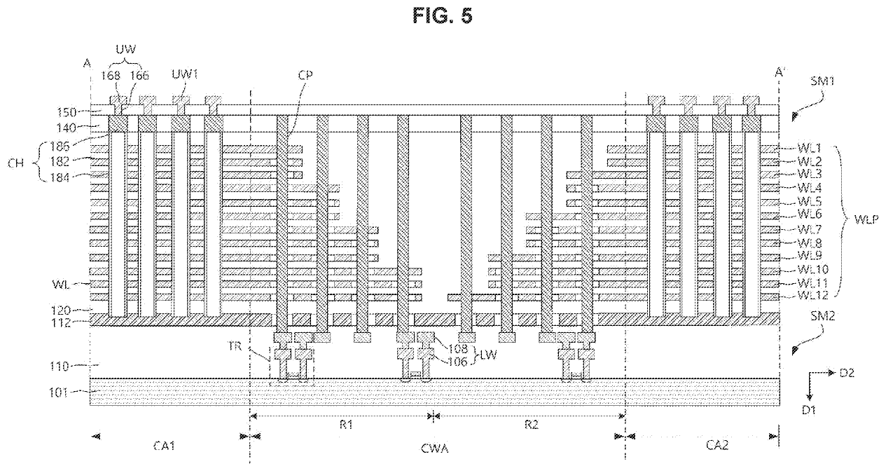

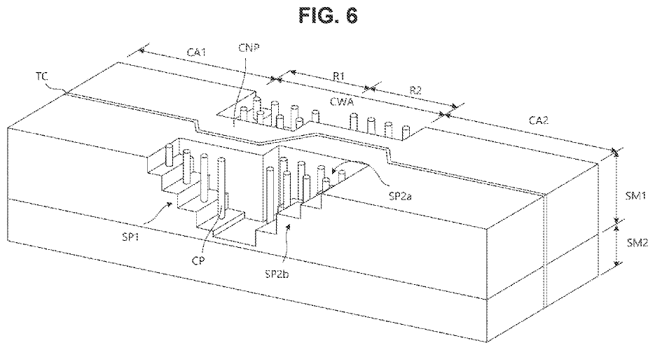

FIG. 4A is a plan view illustrating an example of a memory device including two adjacent memory blocks BLK (a first memory block BLK1 and a second memory block BLK2), and FIG. 4B is a diagram illustrating an example of an order of end staircases in wordlines of FIG. 4A. FIG. 5 is an example cross-sectional view taken along line A-A′ of FIG. 4A. FIG. 6 is an example conceptual perspective view of the memory device of FIG. 4.

In the following drawings, for ease of description, a direction perpendicular to an upper surface of a memory device will be defined as a first direction D1, a direction parallel to the upper surface of the memory device will be defined as a second direction D2, and a direction perpendicular to the first and second directions D1 and D2 will be defined as a third direction D3.

Referring to FIGS. 4A, 4B, 5, and 6, a memory device may have a cell-over-periphery (COP) structure in which a memory cell array and a peripheral circuit are manufactured as separate semiconductor layers and then stacked. For example, the memory device may include a first semiconductor layer SM1 including a memory cell array and a second semiconductor layer SM2 including a peripheral circuit, and the first semiconductor layer SM1 and the second semiconductor layer SM2 may be bonded to be stacked. The memory device having such a structure may be fabricated by manufacturing a first semiconductor layer including a memory cell array and a second semiconductor layer including a peripheral circuit, and then bonding the first semiconductor layer and the second semiconductor layer to each other.

The bonding manner may refer to a manner in which a bonding metal, formed on an uppermost metal layer of the first semiconductor layer, and a second bonding metal, formed on an uppermost metal layer of the second semiconductor layer, are electrically connected to each other. For example, when ta bonding metal is formed of copper (Cu), the bonding manner may be copper-to-copper (Cu-to-Cu) bonding manner, and the bonding metal may be formed of aluminum (Al) or tungsten (W).

Hereinafter, a structure in which the first semiconductor layer SM1 is formed on the second semiconductor layer SM2 will be described as an example. However, the memory device may not have a COP structure, and various modifications for implementation of the memory cell array may be made without departing from the sprit and scope of the present disclosure.

The plurality of memory blocks BLK may be arranged in one direction (the third direction D3 in the drawing). For example, the first and second memory blocks BLK1 and BLK2 may be arranged in the third direction D3.

Each memory block BLK may include a cell region CA and a cell wiring region CWA.

The cell region CA and the cell wiring region CWA may be provided with structures such as a wordline pattern portion WLP and a channel structure CH. A trench TC, penetrating through the structures to extend in the first direction D1, may be provided between memory blocks BLK adjacent to each other, and thus the respective memory blocks BLK may be discriminated from each other.

The cell region CA may be a region in which a plurality of memory cells are disposed, and may include a first cell region CA1 and a second cell region CA2.

The cell wiring region CWA may be provided between the first cell region CA1 and the second cell region CA2. The cell wiring region CWA may provide a connection structure connecting memory cells to other components (for example, pass transistors).

The wordline pattern portions WLP may be provided in the cell region CA and the cell wiring region CWA, and may include WL1, WL2, WL3 to WL9 (WL) spaced apart from each other in a vertical direction (a first direction D1) perpendicular to an upper surface of the substrate. In a portion of the cell wiring region CWA, wordlines WL may extend and ends of the wordlines WL may be implemented to have a staircase shape. Accordingly, the cell wiring region CAW may be referred to as a “staircase region” or a “wordline extension region.”

The wordline pattern portion WLP may include a connection portion CNP, connecting the first cell region CA1 and the second cell region CA2 in the cell wiring region CWA, and staircases at which ends of the wordlines WL are implemented to have a staircase shape. In the wordline pattern portion WLP, the wordlines WL have lengths different depending on stacked locations thereof in the second direction D2 in which the wordlines WL extend toward the first direction D1. As a result, ends of the respective wordlines WL may constitute staircases sequentially descending or ascending in the first direction D1. Accordingly, one of the staircase may correspond to an end of a single wordline WL.

In an example embodiment, the staircase may constitute a single staircase portion. One or more staircase portions may be disposed in each memory block BLK. The staircase portion may be divided into a first region R1 and a second region R2 according to a shape of a staircase including ends of wordlines WL. The first region R1 may correspond to a region having sequentially descending staircases, and the second region R2 may correspond to a region having sequentially ascending staircase. In the example, the wordline pattern portion WLP may extend in the second direction D2 when viewed from above, and may include a first staircase pattern SP1 having a sequentially descending staircase shape and a second staircase pattern SP2 having a sequentially ascending staircase shape. The first staircase pattern SP1 may be provided in the first region R1, and the second staircase pattern SP2 may be provided in the second region R2.

A memory device having such a structure will be described in more detail with reference to FIG. 5.

In an example, the memory device may include circuit patterns such as a first substrate 112, a wordline pattern portion WLP provided on a first substrate 112, a channel structure CH, a contact plug (CP), or the like.

The wordline pattern portion WLP may include a plurality of wordlines WL stacked in the first and second cell regions CA1 and CA2 and the cell wiring region CWA in the first direction D1.

The plurality of wordlines WL may be provided with connection lines, each including an interconnector, a through-via, and the like, for connecting each wordline WL to a peripheral circuit. At least a portion of the connection lines may be provided in a form, penetrating through each wordline WL, to be connected to an underlying peripheral circuit (for example, a pass transistor).

Channel structures CH may be provided in the first and second cell regions CA1 and CA2, and contact plugs CP may be provided in the cell wiring region CWA. Each of the contact plugs CP may be formed of a conductive material, such as a metal, a metal compound, or doped polysilicon, to be electrically connected to corresponding circuit patterns.

In an example, the memory device may further include a peripheral circuit pattern connected to the circuit patterns, and the peripheral circuit pattern may include transistors TR (for example, a pass transistor), provided on an additional second substrate 101, and lower wirings LW. The lower wiring LW may include lower contact vias 106, lower contact pads 108, or the like. In some implementations, the lower wirings LW may have a multilayer structure.

The second substrate 101 may include a semiconductor material such as silicon, germanium, or silicon-germanium, or a group III-V compound such as GaP, GaAs, or GaSb. In some implementations, the substrate may be a silicon-on-insulator (SOI) substrate or a germanium-on-insulator (GOI) substrate.

A lower insulating layer 110 may be provided on the second substrate 101 to cover the peripheral circuit pattern. The lower contact vias 106 may be in contact with impurity regions and/or a gate of the transistor TR.

A first substrate 112 may be provided on the lower insulating layer 110. In some implementations, the first substrate 112 may be disposed below the cell region CA. The first substrate 112 may include, for example, a polysilicon layer or a single crystal silicon layer. A base insulating layer 114 may be provided between the first substrates 112 on the lower insulating layer 110. For example, the base insulating layer 114 may be disposed in a portion through which the contact plug CP penetrates.

A wordline pattern portion WLP, in which a first insulating layer 120 and conductive wordlines WL are repeatedly stacked, may be provided in the cell region CA on the first substrate 112.

The wordlines WL may be formed of a conductive material, for example, a material including metal. For example, the wordlines WL may include tungsten. In some implementations, all of the wordlines WL may be formed of the same material. However, example implementations are not limited thereto, and the wordlines WL may be formed of various materials depending on the type and location of wiring. For example, some patterns and remaining patterns may be formed of different materials. In the drawings, for ease of description, the wordlines WL are illustrated as having similar shapes, similar thicknesses, and similar widths. However, the wordlines WL may be modified to have various shapes, various thicknesses, and various widths. The wordline pattern portion WLP may include a string select line, a ground select line, and the like, other than the wordlines WL, but the wordlines WL will be mainly described for ease of description.

A second insulating layer 140 may be provided on the wordline pattern portion WLP.

The second insulating layer 140 may include an insulating material such as a silicon oxide or a silicon nitride. In some implementations, the second insulating layer 140 may include a TEOS material.

In the cell region CA, a channel hole may be provided to extend to an upper surface of the first substrate 112 through the second insulating layer 140 and the wordline pattern portion WLP, and a channel structure CH may be provided in the channel hole. The channel structure CH may penetrate through the wordlines WL, and may extend in a vertical direction (for example, the first direction D1). The channel structure CH may be in contact with the upper surface of the first structure 112.

The channel structure CH may include a channel 182, a charge storage structure 184, and an upper conductive pattern 186. The upper conductive pattern 186 may be provided on the channel 182, and may fill an upper portion of the channel hole. The channel 182 and the upper conductive pattern 186 may include polysilicon.

An upper surface of the channel structure CH may be disposed to be coplanar with an upper surface of the second insulating layer 140.

In some implementations, in the memory device, a trench TC may be provided to extend in the second direction D2 through the second insulating layer 140 and the wordline pattern portion WLP. The wordlines WL may be cut by the trench, so that a region in which the trench TC is formed may be referred to as a wordline (WL) cutting region. In addition, the trench TC may be provided between individual memory blocks BLK to discriminate adjacent memory blocks BLK. Although not illustrated in the drawing, the first substrate 112 or the base insulating layer 114 may be exposed on a bottom surface of the trench TC. An insulating material may be provided in the trench TC.

In the cell wiring region CWA, a stair pattern may be formed as a pattern in which stacked wordlines WL elongate sequentially. In this case, wordlines WL arranged in a downward direction may be formed to be longer than wordlines arranged in an upward direction, and thus each of the wordlines WL may form a staircase.

The wordline pattern portion WLP may include a first insulating layer 120, corresponding wordlines WL extending in a horizontal direction, a contact plug CP extending in a vertical direction, and insulating patterns insulating the wordlines WL and the contact plug CP from each other. The wordlines WL and the first insulating layer 120 may be alternately stacked.

The wordlines WL may be spaced apart from each other and stacked on the substrate in a vertical direction (for example, the third direction D3), perpendicular to the upper surface of the substrate, and may extend in a direction, parallel to the upper surface of the substrate. In this case, the staircase pattern may include a first stair pattern SP1, descending in the second direction D2, and a second staircase pattern SP2 ascending in the second direction D2. Staircases, provided in the first staircase pattern SP1 and the second staircase pattern SP2, may have different planes for each layer.

Ends of the wordlines WL, for example, staircases may be in contact with the contact plug CP electrically connected to the wordline WL and an underlying circuit pattern (for example, a pass transistor).

In the cell wiring region CWA, contact holes may be provided to penetrate through the second insulating layer 140, the wordlines WL, and the base insulating layer 114 and to extend to an upper portion of the lower insulating layer 110. An upper surface of the lower wiring LW may be exposed to on a bottom surface of each contact hole. A contact plug CP may be provided in the contact hole.

The contact plug CP may extend in the first direction D1 through a portion of the wordlines WL. The contact plug CP may be electrically connected to a wordline WL in a layer and may be insulated from the connected wordlines WL in another layer. A sidewall of the contact plug CP may be in contact with an end of the corresponding wordline WL. The sidewall of the contact plug CP may be insulated from non-corresponding wordlines WL with the insulating pattern ISP interposed therebetween. A lower end portion of the contact plug CP may be in contact with an upper surface of the lower wiring LW.

Accordingly, wordlines WL in each layer and underlying transistors (for example, pass transistors) may be electrically connected by the contact plug CP.

In some implementations, the contact plug CP may include a conductive material, for example, a metal. As an example, the contact plug CP may include a metal such as tungsten (W), copper (Cu), or aluminum (Al). As an example, the contact plug CP may include a barrier metal pattern and a metal pattern.

An upper surface of the contact plug CP may be disposed to be coplanar with an upper surface of the second insulating layer 140.

A third insulating layer 150 may be provided on the second insulating layer 140 in the cell region CA and the cell wiring region CWA.

An upper wiring UW may be provided in the cell region CA to be electrically connected to the channel structure CH. For example, the upper wiring UW may be in contact with the upper conductive pattern 186 of the channel structure CH through the second insulating layer 140. The upper wiring UW may correspond to a bitline. Although not illustrated, a fourth insulating layer may be further provided to cover the upper wiring UW.

Various driving elements, for example, transistors TR may be connected to lower ends of the contact plugs CP. The transistor TR may include a pass transistor connected to the contact plugs CP.

In some implementations, the upper wirings UW and the lower wirings LW may be formed of a conductive material, for example, a single-layer/multilayer/alloy metal, a metal compound, or the like, and the first to third insulating layers 120, 140, and 150 may include an insulating material such as a silicon oxide or a silicon nitride.

In the cell wiring region CWA, a connection portion CNP may be provided in a region in which the first and second staircase patterns SP1 and SP2 are not provided. The connection portion CNP may be a portion to which wordlines WL, corresponding to respective layers in the first cell region CA1 and the second cell region CA2, are connected. The connection portion CNP may correspond to a portion formed by stacking wordlines WL without patterning.

In some implementations, in each memory block BLK, a first staircase pattern SP1 and a second staircase pattern SP2 may be provided in different numbers. For example, m first staircase patterns SP1 may be provided (where m is a positive integer) and n second staircase patterns SP2 may be provided (where n is a positive integer, different from m). For example, in the first memory block BLK1 illustrated in FIG. 4A, a single first staircase pattern SP1 may be provided and two second staircase patterns SP2 (a primary second staircase patterns SP2a and a secondary staircase pattern SP2b) may be provided.

As described above, at least one of the first staircase pattern SP1 and the second staircase pattern SP2 may be provided in plural, so that staircase patterns provided in plural may be arranged in the third direction D3.

In some implementations, the total number of staircases in the first staircase pattern SP1 and staircases in the second staircase pattern SP2 may be equal to the number of the wordlines WL. In addition, the staircases in the first staircase pattern SP1 and the staircases in the second staircase pattern SP2 may be connected to the wordlines WL in a one-to-one correspondence. For example, each wordline WL may correspond to one of staircases constituting the first and second staircase patterns SP1 and SP2, and the wordlines WL may sequentially correspond to an uppermost staircase to a lowermost staircase, among the staircases of the first and second staircase patterns SP1 and SP2. For example, when the wordlines WL includes first, second, third to ninth wordlines WL sequentially stacked in the first direction D1 as illustrated in FIGS. 5 and 6, the sequentially stacked wordlines WL may sequentially correspond to the uppermost staircase to the lowermost staircase, among the staircases of the first and second staircase patterns SP1 and SP2.

FIG. 4B illustrates which staircase pattern is matched with each wordline. In FIG. 4B, numbers are sequentially indicated in the order of wordlines from upper side to a lower side in the third direction.

As illustrated in FIG. 4B, a first wordline WL may correspond to a first staircase of a first staircase pattern SP1, a second wordline WL may correspond to a first staircase of a primary second staircase pattern SP2a, a third wordline WL may correspond to a first staircase of a secondary second staircase pattern SP2b, a fourth wordline WL may correspond to a second staircase of a primary first staircase pattern SP1a, and a fifth wordline WL may correspond to a second staircase of a primary second staircase pattern SP2a. When staircases are provided in such a manner, the first staircase pattern SP1 may be provided with staircases corresponding to first, fourth, seventh, and tenth wordlines WL1, WL4, WL7, and WL10, the primary second staircase pattern SP2a may be provided with staircases corresponding to second, fifth, eighth, and eleventh wordlines WL2, WL5, WL8, and WL11, and the secondary second staircase pattern SP2b may be provided with staircases corresponding to the third, sixth, ninth, and twelfth wordlines WL2, WL6, WL9, and WL12.

As described above, the staircases of the first staircase pattern SP1 and the second staircase pattern SP2, provided in the first region R1 and the second region R2, are formed staircases having substantially the same as corresponding wordlines WL, so that the staircases may have different heights. For example, the staircases in the first staircase pattern SP1 may include staircases descending sequentially and having different heights, and the staircases in the second staircase pattern SP2 may include staircases ascending sequentially and having different heights. In addition, both the staircases in the first staircase pattern SP1 and the staircases in the second staircase pattern SP2 may be provided at different heights.

However, when the first and second staircase patterns SP1 and SP2 are provided in plural, correspondence of each staircase to the wordlines WL may be modified in various manners. For example, the first and second wordlines WL1 and WL2 may correspond to staircases of the first staircase pattern SP1, the third wordline WL3 may corresponds to the primary second staircase pattern SP2a, and the fourth wordline WL4 may correspond to the secondary second staircase pattern SP2b. In addition, the number of staircases included in a single first staircase pattern SP1 and the number of staircases included in a single second staircase pattern SP2 may be the same, but are not limited thereto and may be different from each other.

A size (for example, an area or a volume) of the memory device according to the above-described implementations may be significantly reduced due to a difference in numbers between the first staircase pattern SP1 and the second staircase pattern SP2. As at least one of the two staircase patterns is provided in plural, a width of the memory device in the second direction D2 may be significantly reduced, as compared with the related art having a staircase pattern formed to extend in only one direction (for example, a second direction D2).

According to the existing technique, only one staircase pattern is provided and staircases descending or ascending in a second direction D2 are formed, so that an area equivalent to an overall length of staircases is required as the number of wordlines WL increases. Meanwhile, in some implementations, a staircase pattern extending in the second direction D2 may be provided in plural and first and second staircase patterns SP1 and SP2 in descending and ascending directions may be combined to reduce the overall length of staircases, and thus an area of a single memory block BLK may be significantly reduced. In addition, cell regions CA may be disposed on opposite sides of cell wiring region CWA and a connection portion CNP may connect the cell regions CA in consideration of a process margin when the first and second staircase patterns SP1 and SP2 are manufactured, and sequentially descending staircases and re-ascending staircase may be disposed in the cell wiring region CWA between the two cell regions CA to significantly reduce defects when the first and second staircase patterns SP1 and SP2 are manufactured.

In some implementations, a memory block BLK may have a width varying depending on a location thereof because the number of first and second staircase patterns SP1 and SP2 varies depending on the first and second regions R1 and R2. For example, a width of the first region R1 in the third direction D3 may be different from a width of the second region R2 in the third direction D3. For example, when a width of the first region is referred to as a first width W1 and a width of the second region R2 is referred to as a second width W2 in the first memory block BLK1, the first width W1 of the first region R1 including a small number of staircase patterns may be smaller than the second width W2 of the second region R2 including a large number of staircase patterns.

Accordingly, the memory block BLK may be divided by a trench TC, so that at least a portion of the trench TC may have an inclined portion which is not parallel to the second direction D2 when viewed from above. In addition, the memory block BLK may have a concave or convex shape in the third direction D2 due to such an inclined portion when viewed from above.

Since the memory block BLK has a width varying depending on a location thereof, two adjacent memory blocks BLK may be disposed in such a manner that a concave portion and a convex portion are interdigitated, and thus an area occupied by the two memory blocks BLK may be significantly reduced. For example, when only staircases having a straight line shape are used as in the existing technique, a connection portion is provided in the form of a straight line to cause difficulty in forming additional staircases. Meanwhile, in some implementations, a trench may be formed to have an inclined portion, and thus a memory block may have a large width in a partial region. In this case, an additional staircase pattern may be formed in a region having a large width. Accordingly, a larger number of staircase patterns may be formed in a partial region having a large width to reduce an area of a staircase region, as compared with the case it would be otherwise.

Returning to FIGS. 4A and 6, when two adjacent memory blocks BLK are referred to as a first memory block BLK1 and a second memory block BLK2, the first and second memory blocks BLK1 and BLK2 may be in point symmetry, and thus may be disposed to be interdigitated with each other. This will be described below in more detail.

The first memory block BLK1 and the second memory block BLK2 may have widths, each varying depending on the first and second regions R1 and R2, and may have an interdigitated shape. In the first memory block BLK1 and the second memory block BLK2, the number of staircase patterns may vary depending on the first and second regions R1 and R2. For example, in the first memory block BLK1, the number of the first staircase patterns SP1 may be smaller than the number of the second staircase patterns SP2, and in the second memory block BLK1, the number of the first staircase patterns SP1 may be larger than the number of the second staircase patterns SP2. As a result, a relatively narrow portion of the first memory block BLK1 may be interdigitated with a relatively wide portion of the second memory block BLK2, and a relatively wide portion of the first memory block BLK1 may be interdigitated with a relatively narrow portion of the second memory block BLK2.

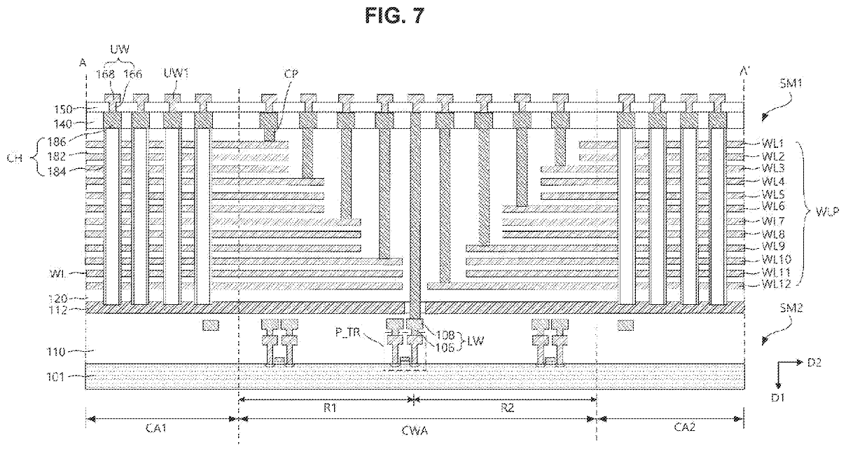

FIG. 7 is a cross-sectional view illustrating an example memory device including a wiring connected to wordlines. The wiring connected to wordlines is implemented to be different in the memory device in some implementations. In the above-described implementations, a contact plug penetrating through wordlines may be provided to be an underlying peripheral circuit, but a connection line may be provided in other forms.

Referring to FIG. 7, connection lines CL extending in a vertical direction may be provided in a cell wiring region CWA. A portion of the connection lines CL may be provided in the form of a through-via connected to an upper wiring having a lower end portion contacting ends of wordlines WL, for example, an upper surface of a staircase and an upper end portion disposed on an upper side. The upper wiring may be connected to an underlying peripheral circuit (for example, a pass transistor) via various paths (for example, an additional through-via), and a shape and a connection relationship of such connection lines CL are not limited thereto.

In some implementations, when the memory device has a COP structure, a first semiconductor device and a second semiconductor device may be provided in a form, different from the above-described structure.

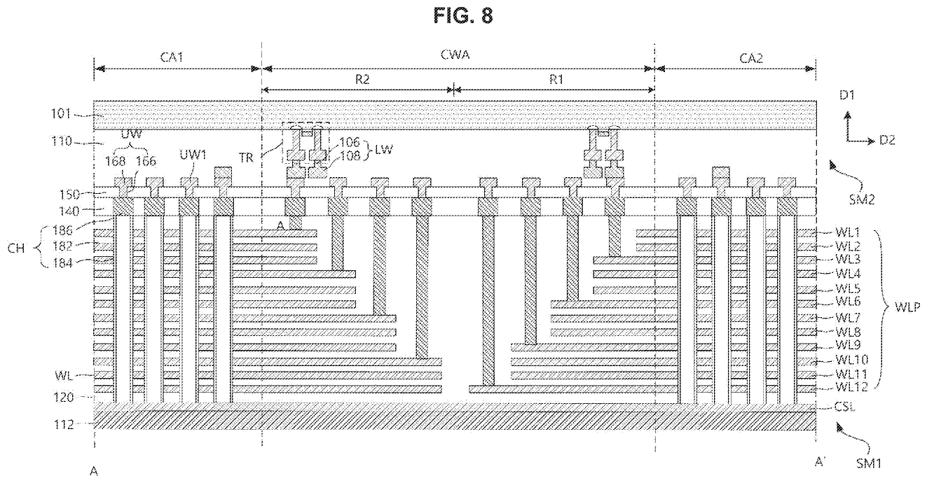

FIG. 8 is a cross-sectional view illustrating another example memory device.

Referring to FIG. 8, a memory device may have a structure in which a first semiconductor layer SM1 and a second semiconductor layer SM2 are bonded to each other after one of the first and second semiconductor layers SM1 and SM2 is inverted. For example, the second semiconductor layer SM2 may be disposed on the first semiconductor layer SM1. In this case, the second semiconductor layer SM2 may be provided in an inverted form.

Alternatively, although not illustrated in the drawing, the memory device may be fabricated by inverting the first semiconductor layer SM1 and bonding the inverted first semiconductor layer SM1 onto the second semiconductor layer SM2. In this case, wordline patterns WLP of the first semiconductor layer SM1 may have a reverse staircase shape. In the reverse staircase shape, wordlines WL constituting staircases may have substantially the same feature portion as in the above-described implementations.

However, the first semiconductor layer SM1 or the second semiconductor layer SM2 may be inverted to modify a portion of the wordlines WL, other circuit patterns, and wirings connected to peripheral circuits. As described in the example, when the second semiconductor layer SM2 is inverted and bonded to the first semiconductor layer SM1, a connection between an element such as the wordlines WL and the peripheral circuit may be facilitated.

In some implementations, a plurality of interdigitated memory blocks are arranged, and thus a memory device having a significantly reduced area may be implemented. As an example, the number of first and second staircase patterns SP1 and SP2 in a single memory block BLK may vary in some implementations.

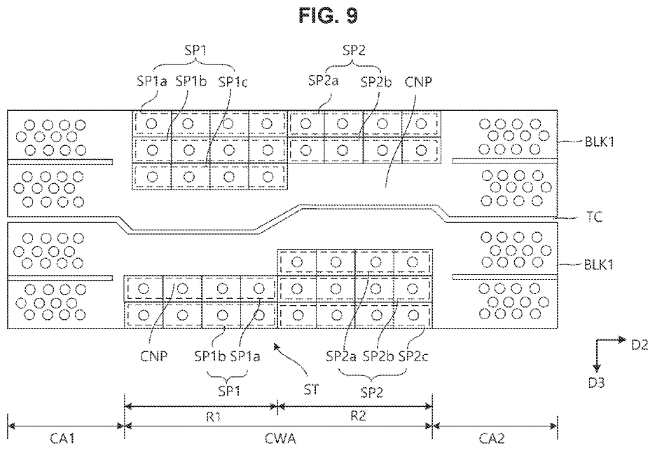

FIG. 9 is a plan view illustrating an example memory device. In the memory device, the numbers of first and second staircase patterns SP1 and SP2 are set to be different from those in the above-described implementations.

Referring to FIG. 9, in the memory block BLK, a first memory block BLK1 may include two first staircase patterns SP1a and SP1b, provided in a first region R1, and three second staircase patterns SP2a, SP2b, and SP2c provided in a second region R2. A second memory block BLK2 may include three first staircase patterns SP1a, SP1b, and SP1c, provided in the first region R1, and two second staircase patterns SP2a and SP2b provided in the second region R2.

As described above, the number of first staircase patterns SP1 and the number of second staircase patterns SP2 may be variously applied to the memory block BLK, and the smaller a size of the memory block BLK, the greater the effect of reducing the size may be, as compared with an existing memory block BLK.

In the above-describe implementations, a description has been provided on an example in which two adjacent memory blocks are interdigitated with each other, but example implementations are not limited thereto. For example, the memory device may have a shape in which three adjacent memory blocks are sequentially interdigitated with each other.

In this case, when three memory blocks sequentially disposed in a third direction D3 are referred to as first to third memory blocks, at least one of the first to third memory blocks may be a block having different numbers of first staircase patterns and second staircase patterns. For example, each of the three memory blocks may have different numbers of first and second staircase patterns and, among the three memory blocks, two memory blocks may have different numbers of first and second staircase patterns and a remaining memory block may have the same number of first and second staircase patterns.

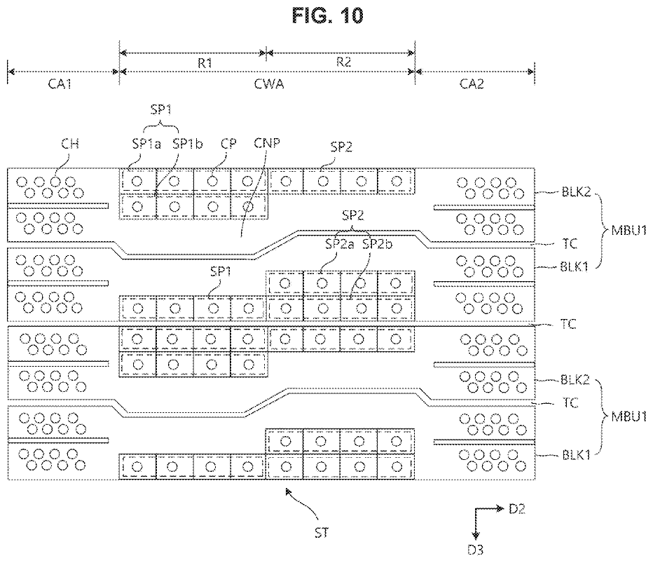

FIG. 10 is a plan view illustrating an example of disposing memory blocks in a memory device.

Referring to FIG. 10, two adjacent interdigitated memory blocks BLK1 and BLK2 may constitute a single memory block unit MBU. Memory block units MBU may have substantially the same shape.

The memory block unit MBU may be provided in plural to be arranged in a third direction D3. For example, each memory block unit MBU may include a first memory block BLK1 and a second memory bock BLK2 adjacent to each other and a plurality of memory block units MBU may be arranged in the third direction, so that the first memory block BLK1 and the second memory block BLK2 may be alternately disposed.

In this case, a trench TC between the first memory block BLK1 and the second memory block BLK2 may have an inclined portion including at least a portion inclined when viewed from above.

In some implementations, a trench TC in which two interdigitated memory blocks BLK1 and BLK2 are adjacent to each other may have an inclined portion, or a trench TC surrounding external sides of the two memory blocks BLK1 and BLK2 may not have an inclined portion. However, example implementations are not limited thereto, and a trench TC surrounding two adjacent interdigitated memory block BLK or a trench surrounding non-interdigitated memory blocks BLK may have an inclined portion.

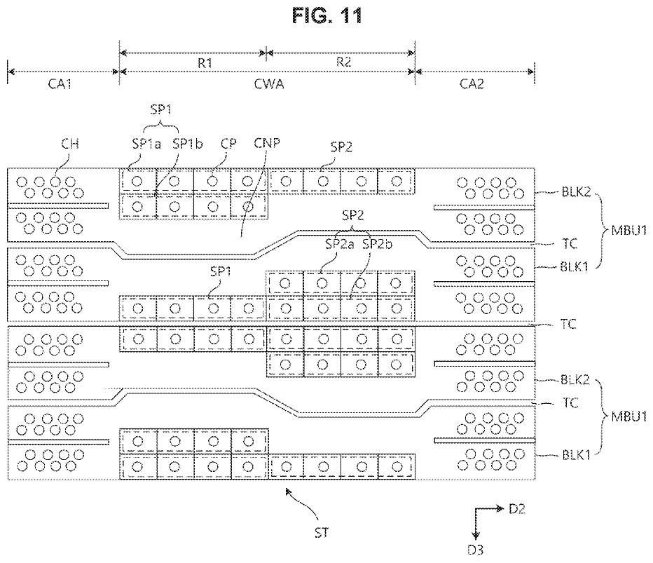

FIG. 11 is a plan view illustrating another example of disposing memory blocks in a memory device.

Referring to FIG. 11, two adjacent interdigitated memory blocks BLK may constitute two memory block units MBU, for example, a first memory block unit MBU1 and a second memory block unit MBU2, and the first and second memory block units MBU1 and MBU2 may be provided in plural to be alternately arranged (however, only one first memory block unit MBU1 and only one second memory block unit MBU2 are illustrated in the drawing). The second memory block unit MBU2 may be interdigitated with the first memory block unit MBU1 to be vertically symmetrical with respect thereto.

In the above-described implementations, a single staircase portion is illustrated as being formed in a single memory block, but example implementations are not limited thereto and a plurality of staircase portions may be formed in a single memory block. For example, two or more staircase portions may be formed in a single memory block.

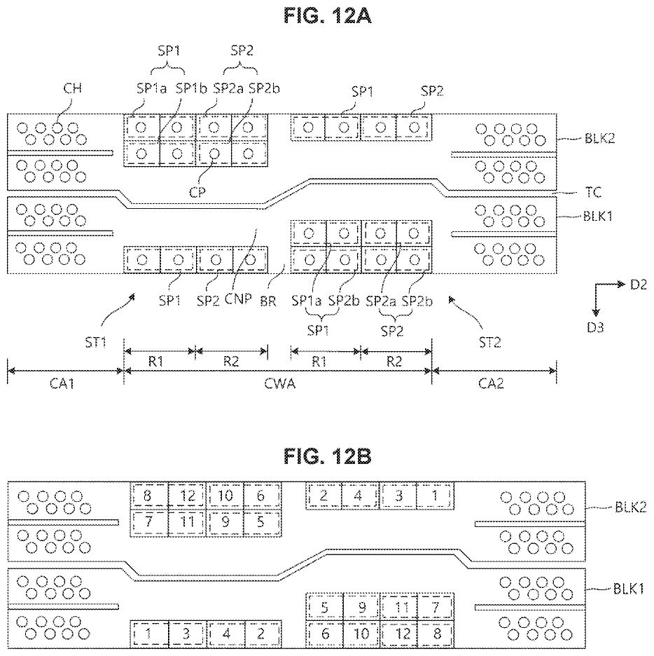

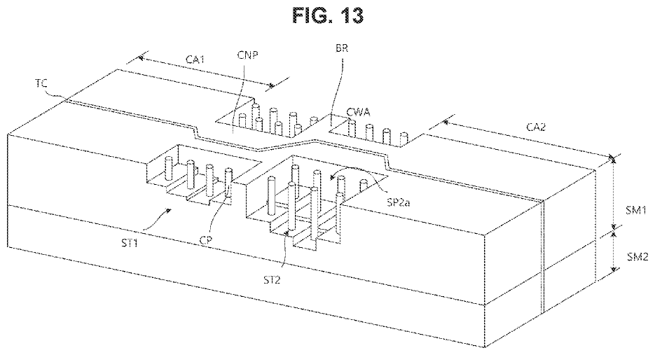

FIG. 12A is a plan view illustrating another example of a memory device including two adjacent memory blocks, FIG. 12B is a diagram illustrating an example of an order of end staircases in wordlines of FIG. 12A, and FIG. 13 is a conceptual perspective view of another example of a memory device including two staircase portions in a single memory block.

Referring to FIGS. 12A, 12B, and 13, in a single memory block (a first memory block BLK1 in the drawings), a plurality of staircase portions, for example, two staircase portions may be provided. For example, the staircase portion may include a first staircase portion ST1 and a second staircase portion ST2. The number of the staircase portions is not limited thereto, and three or more staircase portions may be provided depending on circumstances.

In the example, the first staircase portion ST1 and the second staircase portion ST2 may be spaced apart from each other in a second direction D2. A bridge BR may be provided between the first and second staircase ST1 and ST2 spaced apart from each other. The first staircase ST1 and the second staircase ST2 may have a shape depressed from an upper surface in a third direction D3. A bridge (BR) portion, in which the first staircase ST1 and the second staircase ST2 are not disposed, may have an upper surface having the same height as upper surfaces of a first cell region CA1 and a second cell region CA2 and a connection portion CNP.

In the example, each of the first and second staircase portions ST1 and ST2 may have a first staircase pattern SP1 and a second staircase pattern SP2. For example, the first staircase portion ST1 may include a first staircase pattern SP1, having sequentially descending staircases, and a second staircase pattern SP2 having a sequentially ascending staircase shape, and the first staircase pattern SP1 may be provided in a first region R1 and the second staircase pattern SP2 may be provided in a second region R2. The second staircase portion ST2 may include a first staircase pattern SP1, having sequentially descending staircases, and a second staircase pattern SP2 having a sequentially ascending staircase shape, and the first staircase pattern SP1 may be provided in the first region R1 and the second staircase pattern SP2 may be provided in the second region R2.

In the example, the first staircase portion ST1 and the second staircase portion ST2 may have different numbers of staircase patterns. For example, the first staircase portion ST1 may have a single first staircase pattern SP1 and a single second staircase pattern SP2, and the second staircase portion ST2 may have two first staircase patterns SP1 and two second staircase patterns SP2. Accordingly, in the second staircase portion ST2, the first staircase pattern SP1 may include a primary first staircase pattern SP1a and a secondary first staircase pattern SP1b. The second staircase pattern SP2 may include a primary second staircase pattern SP2a and a secondary second staircase pattern SP2b. In this case, the two first staircase patterns SP1a and SP1b and the two second staircase patterns SP2a and SP2b of the second staircase portion ST2 may be respectively disposed in the third direction D3.

Staircases, present in the first staircase portion SP1 and the second staircase portion SP2, may correspond to wordlines WL in a one-to-one correspondence. For example, each wordline WL may correspond to one of the staircases included in the first and second staircase portions ST1 and ST2, and the wordlines WL may sequentially correspond to an uppermost staircase to a lowermost staircase, among the staircases of the first and second staircase portions ST1 and ST2.

FIG. 12B illustrates which staircase pattern is matched with each wordline, which is expressed by numbers. The numbers are arranged in the order of wordlines from an upper side to a lower side in a third direction. As illustrated in FIG. 12B, a first wordline to a fourth wordline may corresponding to the first staircase pattern SP1 and the second staircase pattern SP2 of the first staircase portion ST1, and a fifth wordline to a twelfth wordline may correspond to the second staircase portion ST2 and may respectively correspond to a primary first staircase pattern SP1a and a secondary first staircase pattern SP1b, a primary second staircase pattern SP2a, and a secondary second staircase pattern SP2b in a one-to-one correspondence. Staircase patterns and staircases corresponding to each wordline may be variously matched in a configuration in which a second staircase pattern is disposed next to a first staircase pattern, for example, within a limit in which descending staircases and ascending staircases are sequentially disposed.

An example implementation has been described under the assumption that twelve wordlines are provided and twelve staircases are provided, but the number of wordlines may be different therefrom and the number of wordlines matching the first and second staircase portions may also be different therefrom.

As described above, when two staircase portions are provided, a bridge may be provided between two staircase portions, spaced apart from each other, to easily manufacture a structure in which a staircase portion is formed.

The present disclosure has been described with reference to example implementations but it is to be understood that the present disclosure may be variously changed and modified without departing from the spirit and scope of the present disclosure described in the claims by a person skilled in the art or a person of ordinary skill in the art.

For example, each of the above-described implementations discloses that some configurations are modified within the sprit and scope of the present disclosure, but it is to be understood that they may be combined in various manners unless incompatible therewith. For example, a memory block having a single staircase portion has been described in some implementations and a memory block having two staircase portions has been described in other implementations, but it is to be understood that various modifiable implementations in a memory block having a single staircase portion may be applied to a memory block having two staircase portions.

Therefore, the technical scope of the present disclosure should not be limited to the contents described in the detailed description of the specification but should be defined by the claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

As set forth above, according to example implementations, a memory device having high integration and significantly reduced size, achieved by optimizing a structure in an element, may be provided.

What is claimed is:

1. A memory device, comprising:
a plurality of memory blocks, each including a cell region and a cell wiring region, wherein at least one memory block of the plurality of memory blocks comprises:
a wordline pattern portion provided in the cell region and the cell wiring region and including wordlines spaced apart from each other and stacked in a first direction; and
a channel structure provided in the cell region to extend in the first direction, wherein the wordline pattern portion extends a second direction, perpendicular to the first direction, when viewed from above, and has at least one staircase portion comprising a first staircase pattern, having sequentially descending staircases, and a second staircase pattern, having sequentially ascending staircases, and wherein the first staircase pattern and the second staircase pattern are provided in different numbers in the at least one memory block.

2. The memory device of claim 1, wherein the at least one staircase portion comprises a first staircase portion and a second staircase portion spaced apart from the first staircase portion in the second direction.

3. The memory device of claim 2, wherein the number of the first staircase pattern of the first staircase portion and the number of the first staircase pattern of the second staircase portion are different from the number of the second staircase pattern of the first staircase portion and the number of the second staircase pattern of the second staircase portion.

4. The memory device of claim 1, wherein the staircases, constituting the first staircase pattern and the second staircase pattern, correspond to the wordlines in a one-to-one correspondence.

5. The memory device of claim 4, wherein the wordlines sequentially correspond to an uppermost staircase, among the staircases of the first and second staircase patterns, to a lowermost staircase among the staircases of the first and second staircase patterns.

6. The memory device of claim 5, wherein in the wordlines, respective staircases of the first and second staircase patterns have different heights.

7. The memory device of claim 1, wherein:
in the staircase portion, the first staircase pattern is provided in a first region and the second staircase pattern is provided in a second region adjacent to the first region in the second direction; and
the first staircase pattern comprises m first staircase patterns, the second staircase pattern comprises n second staircase patterns, m is a positive integer, and n is a positive integer different from m.

8. The memory device of claim 7, wherein when at least one of the first staircase pattern or the second staircase pattern includes a plurality of staircase patterns, the plurality of first staircase patterns or the plurality of second staircase patterns are arranged in a third direction, perpendicular to the first direction and the second direction.

9. The memory device of claim 8, wherein the plurality of memory blocks are arranged in the third direction, and a trench is provided between two adjacent memory blocks and has an inclined portion inclined in the second direction when viewed from above.

10. The memory device of claim 7, wherein when two adjacent memory blocks are a first memory block and a second memory block, the first and second memory blocks have different widths depending on a disposition of the staircase portion in the first and second regions, and have an interdigitated shape.

11. The memory device of claim 10, wherein:
in the first memory block, the number of the first staircase pattern is smaller than the number of the second staircase pattern; and
in the second memory block, the number of the first staircase pattern is larger than the number of the second staircase pattern.

12. The memory device of claim 10, wherein at least two adjacent memory blocks, having the interdigitated shape, constitute a memory block unit, and the memory block unit includes a plurality of units sequentially disposed in a third direction, perpendicular to the first direction and the second direction.

13. The memory device of claim 10, wherein the memory blocks comprise:
a first memory block unit comprising two adjacent memory blocks having the interdigitated shape; and
a second memory block unit comprising two adjacent memory blocks having the interdigitated shape and being vertically symmetrical with respect to the first memory block unit, and the first memory block unit includes a plurality of first units, the second memory block unit includes a plurality of second units, and the plurality of first units and the plurality of second units are alternately disposed.

14. The memory device of claim 1, further comprising:
connection lines extending to the cell wiring region in a vertical direction to be electrically connected to one of the wordlines.

15. The memory device of claim 14, further comprising:
contact plugs extending to the cell wiring region in the vertical direction and electrically connected to a corresponding wordline, among the wordlines and insulated from remaining wordlines other than the corresponding wordline.

16. A memory device, comprising:
a first semiconductor layer comprising a memory cell array; and
a second semiconductor layer comprising a peripheral circuit and bonded to the first semiconductor layer, wherein the memory cell array comprises a plurality of memory blocks, each comprising a cell region and a cell wiring region, and at least one memory block of the plurality of memory blocks comprises:
a wordline pattern portion provided in the cell region and the cell wiring region and comprising wordlines spaced apart from each other and stacked in a first direction; and
a channel structure provided in the cell region to extend in the first direction, wherein the wordline pattern portion extends in a second direction, perpendicular to the first direction, when viewed from above, and has at least one staircase portion comprising a first staircase pattern having sequentially descending staircases and a second staircase pattern having sequentially ascending staircases, and wherein the first staircase pattern and the second staircase pattern are provided in different numbers in the at least one memory block.

17. The memory device of claim 16, wherein the staircases, constituting the first staircase pattern and the second staircase pattern, correspond to the wordlines in a one-to-one correspondence.

18. A method of manufacturing a memory device set forth in claim 16, the method comprising:
manufacturing a first semiconductor layer comprising a memory cell array provided on a first substrate;
manufacturing a second semiconductor layer comprising a peripheral circuit provided on a second substrate; and
bonding the first semiconductor layer and the second semiconductor layer together.

19. The method of claim 18, further comprising:
disposing the second semiconductor layer on the first semiconductor layer before bonding the first semiconductor layer and the second semiconductor layer together.

20. The method of claim 18, further comprising:
inverting one of the first semiconductor layer and the second semiconductor layer before disposing the first semiconductor layer and the second semiconductor layer.
